(19) United States
(12) Patent Application Publication
(10) Pub. No.: US 2016/0068959 A1
(43) Pub. Date: Mar. 10, 2016

(54) ATMOSPHERIC EPITAXIAL DEPOSITION CHAMBER

(71) Applicant: Applied Materials, Inc., Santa Clara, CA (US)

(72) Inventors: Shu-Kwan LAU, Sunnyvale, CA (US); Mehmet Tugrul SAMIR, Mountain View, CA (US); Nyi O. MYO, San Jose, CA (US); Aaron MILLER, Sunnyvale, CA (US); Aaron Muir HUNTER, Santa Cruz, CA (US); Errol Antonio C. SANCHEZ, Tracy, CA (US); Paul BRILLHART, Pleasanton, CA (US); Joseph M. RANISH, San Jose, CA (US); Kartik SHAH, Sunnyvale, CA (US); Dennis L. DEMARS, Santa Clara, CA (US); Satheesh KUPPURAO, San Jose, CA (US)

(21) Appl. No.: 14/845,998

(22) Filed: Sep. 4, 2015

Related U.S. Application Data
(63) Continuation of application No. 14/826,310, filed on Aug. 14, 2015.
Application No. 14/826,310 is a continuation of application No. 14/826,287, filed on Aug. 14, 2015.
Application No. 14/826,287 is a continuation of application No. 14/826,065, filed on Aug. 13, 2015.
Application No. 14/826,065 is a continuation of application No. 14/584,441, filed on Dec. 29, 2014.
(60) Provisional application No. 62/046,414, filed on Sep. 5, 2014.
(60) Provisional application No. 62/046,451, filed on Sep. 5, 2014.
(60) Provisional application No. 62/046,377, filed on Sep. 5, 2014.
(60) Provisional application No. 62/046,400, filed on Sep. 5, 2014.
(60) Provisional application No. 62/046,559, filed on Sep. 5, 2014.

(51) Int. Cl. C23C 16/48; C23C 16/44; C23C 16/458

(52) U.S. Cl. CPC C23C 16/48; C23C 16/458; C23C 16/4412

(57) ABSTRACT

Implementations described herein disclose epitaxial deposition chambers and components thereof. In one implementation, a chamber can include a substrate support positioned in a processing region, a radiant energy assembly comprising a plurality of radiant energy sources, a liner assembly having an upper liner and a lower liner, and a dome assembly positioned between the substrate support and the radiant energy assembly. The epitaxial deposition chambers described herein allow for processing of larger substrates, while maintaining throughput, reducing costs and providing a reliably uniform deposition product.

### CROSS-REFERENCE TO RELATED APPLICATIONS

This application claims priority to U.S. Provisional Patent Application Ser. No. 62/046,559, filed on Sep. 5, 2014, to U.S. patent application Ser. No. 14/584,441, filed on Dec. 29, 2014, to U.S. Provisional Patent Application Ser. No. 62/046,400, filed on Sep. 5, 2014, to U.S. patent application Ser. No. 14/826,065, filed on Aug. 13, 2015, to U.S. Provisional Patent Application Ser. No. 62/046,377, filed on Sep. 5, 2014, to U.S. Provisional Patent Application Ser. No. 62/046,414, filed on Sep. 5, 2014, to U.S. patent application Ser. No. 14/826,310, filed on Aug. 20, 2015, to U.S. Provisional Patent Application Ser. No. 62/046,451, filed on Sep. 5, 2014, and to U.S. patent application Ser. No. 14/826,287, filed on Aug. 14, 2015, which are incorporated by reference herein.

### BACKGROUND

1. Field

Implementations of the disclosure generally relate to an epitaxial deposition chamber utilized in semiconductor fabrication processes.

2. Description of the Related Art

Modern processes for manufacturing semiconductor devices require precise adjustment of many process parameters to achieve high levels of device performance, product yield, and overall product quality. For processes that include the formation of semiconductive layers on substrates with epitaxial (“EPI”) film growth, numerous process parameters have to be carefully controlled, including the substrate temperature, the pressures and flow rates precursor materials, the formation time, and the distribution of power among the heating elements surrounding the substrate, among other process parameters.

There is an ongoing need for increasing yield of devices, as well as the number of devices, per substrate. Utilization of substrates with a larger surface area for device formation increases the number of devices per substrate. However, increasing the surface area of the substrate creates numerous process parameter issues. For example, mere scaling-up of chamber components to accommodate larger substrate sizes has been found to not be sufficient to achieve desirable results.

Thus, there is a need for an improved EPI process chamber that provides for uniform deposition of semiconductive layers on a substrate having a larger usable surface area.

### SUMMARY

Implementations described herein relate to epitaxial deposition chambers and components thereof. In one implementation, a chamber can include a substrate support positioned in a processing region; a radiant energy assembly comprising a plurality of radiant energy sources; a liner assembly having an upper liner and a lower liner; a dome assembly positioned between the substrate support and the radiant energy assembly, the dome assembly comprising an upper dome and a lower dome, the upper dome comprising a convex central window portion having a width; a window curvature, the window curvature defined by the ratio of the radius of curvature to the width being at least 10:1; and a peripheral flange having a planar upper surface; a planar lower surface; and an angled flange surface, the peripheral flange engaging the central window portion at a circumference of the central window portion, the angled flange surface having a first surface with a first angle that is less than 35 degrees as measured from the planar upper surface, the dome assembly and the liner assembly forming the boundaries of the processing region; and an inject insert in fluid connection with the liner assembly.

In another implementation, a chamber can include a substrate support having an outer peripheral edge circumscribing a pocket, wherein the pocket has a concave surface that is recessed from the outer peripheral edge; and an angled support surface disposed between the outer peripheral edge and the pocket, wherein the angled support surface is inclined with respect to a horizontal surface of the outer peripheral edge; and a dome assembly positioned between the substrate support and the radiant energy assembly, the dome assembly comprising an upper dome and a lower dome, the upper dome including a convex central window portion having a width; a height; and a window curvature, the window curvature defined by the ratio of the width to the height being at least 10:1; and a peripheral flange having a planar upper surface; a planar lower surface; and an angled flange surface, the peripheral flange engaging the central window portion at a circumference of the central window portion, the angled flange surface having a first surface that forms a first angle with the planar upper surface that is less than 35 degrees.

In another implementation, a chamber can include a liner assembly, comprising a cylindrical body having an outer surface and an inner surface, the outer surface having an outer circumference less than a circumference of the semiconductor process chamber, the inner surface forming the walls of a process volume; and a plurality of gas passages formed in connection with the cylindrical body; an exhaust port positioned opposite to the plurality of gas passages; a crossflow port positioned non parallel to the exhaust port; and a thermal sensing port positioned separate from the crossflow port; and an inject insert in fluid connection with the liner assembly, the inject insert comprising a monolithic body having an inner connecting surface for connecting with the liner assembly; and an exterior surface to connect with a gas delivering device; a plurality of inject ports formed through the monolithic body, each inject port forming an opening in the interior connecting surface and the exterior surface, the plurality of inject ports creating at least a first zone with a first number of inject ports of the plurality of inject ports, a second zone with a second number of inject ports of the plurality of inject ports, the second number of inject ports being different from the first number of inject ports, and a third zone with a third number of inject ports of the plurality of inject ports, the third number of inject ports being different from the first number of inject ports and the second number of inject ports; and a plurality of inject inlets, each of the plurality of inject inlets being connected with at least one of the plurality of inject ports.

### BRIEF DESCRIPTION OF THE DRAWINGS

So that the manner in which the above-recited features of the present disclosure can be understood in detail, a more particular description of the disclosure, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic sectional view of an epitaxial deposition chamber according to implementations of the present disclosure.

FIG. 2 illustrates a schematic sectional view of a backside heating process chamber having a liner assembly, according to another implementation.

FIG. 3A depicts a top view of an upper liner, according to implementations described herein.

FIG. 3B depicts a side view of the upper liner, according to the implementations of FIG. 3A.

FIGS. 4A and 4B depict top and side views of a lower liner, according to one implementation.

FIG. 5 depicts a top view of a lower liner, according to another implementation.

FIG. 6A depicts a schematic diagram of an inject insert in accordance with one implementation.

FIG. 6B is a side view of an inject insert, according to one implementation.

FIG. 7 is a cut away overhead view of an inject insert and gas line combination, according to one implementation.

FIG. 8 is a side view of a multi-tier inject insert, according to one implementation.

FIG. 9 is a schematic isometric view of a substrate support, according to one implementation.

FIG. 10 is a cross-sectional view of the substrate support of FIG. 9.

FIG. 11 is an enlarged cross-sectional view of the substrate support of FIG. 10.

FIG. 12 is a schematic isometric view of a pre-heat ring according to one implementation of the present disclosure.

FIG. 13 is a cross-sectional view of the pre-heat ring of FIG. 12.

FIG. 14 is an enlarged cross-sectional view of the pre-heat ring of FIG. 13.

FIG. 15A depicts a schematic diagram of an upper dome in accordance with one implementation.

FIG. 15B is a side view of an upper dome, according to one implementation.

FIG. 15C depicts a close up view of the connection between the peripheral flange and the central window portion, according to one implementation.

To facilitate understanding, identical reference numerals have been used, where possible, to designate identical elements that are common to the figures. The figures are not drawn to scale and may be simplified for clarity. It is contemplated that elements and features of one implementation may be beneficially incorporated in other implementations without further recitation.

### DETAILED DESCRIPTION

In the following description, for purposes of explanation, numerous specific details are set forth in order to provide a thorough understanding of the present disclosure. In some instances, well-known structures and devices are shown in block diagram form, rather than in detail, in order to avoid obscuring the present disclosure. These implementations are described in sufficient detail to enable those skilled in the art to practice the disclosure, and it is to be understood that other implementations may be utilized and that logical, mechanical, electrical, and other changes may be made without departing from the scope of the present disclosure.

Implementations of the present disclosure generally describe an atmospheric epitaxial deposition chamber and components thereof. Exemplary components which are disclosed herein include, but are not limited to heat sources including lamp modules and reflectors, dome assemblies including an upper dome and a lower dome, liners, inject inserts, substrate support, and preheat rings.

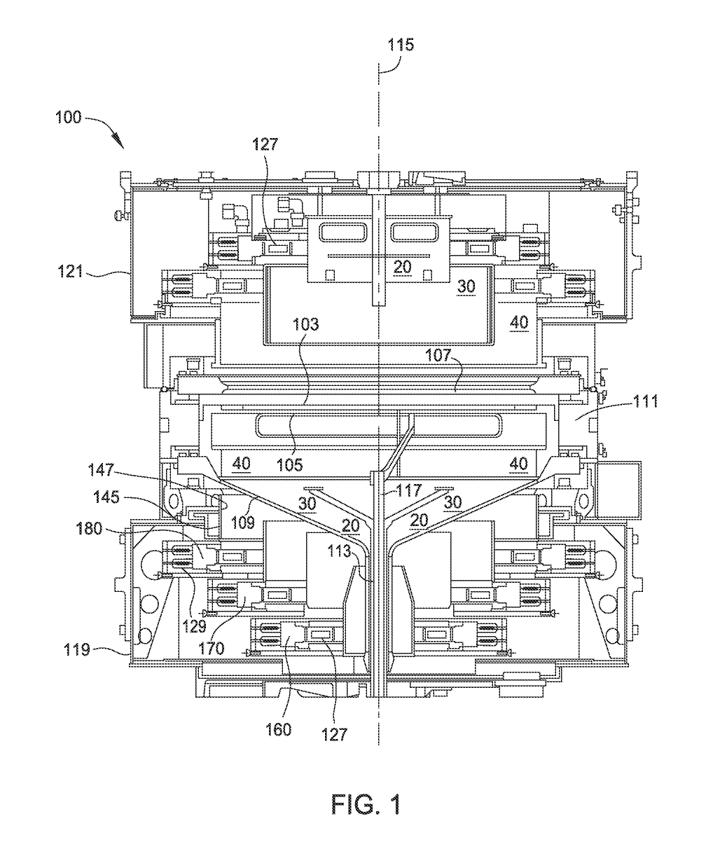

The atmospheric deposition chambers described herein can include one or more of the implementations described below. In one example, an atmospheric deposition chamber includes heat sources including lamp modules and reflectors and dome assemblies including an upper dome and a lower dome as described below. In another example, an atmospheric deposition chamber includes liners, inject inserts, substrate support, and preheat rings as described below. The benefits as described with reference to FIGS. 1-15C can be either incorporated into atmospheric epitaxial deposition chambers by either partially or completely incorporating one or more of the respective described implementations. Various implementations of the present disclosure are discussed in more detail below.

FIG. 1 illustrates a schematic sectional view of an epitaxial deposition chamber 100 according to implementations of the present disclosure. While the epitaxial deposition chamber is shown, other chambers such as a chemical vapor deposition chamber or a rapid thermal processing chamber can also be benefited by implementations of the present disclosure. A substrate 103, which might be a thin wafer of silicon having a diameter of 200 mm, 300 mm, or 450 mm, for example, is supported on a substrate support 105 mounted within the chamber within the chamber 100. Substrate support 105 may be made, for example, of graphite, silicon carbide or graphite coated with silicon carbide, and is in the form of a thin disc such that it has relatively low thermal mass. Substrate support 105 may have a diameter larger than the diameter of the substrate to be processed. Thus, for a 450 mm substrate, the substrate support 105 would have a diameter greater than or equal to about 450 mm. Representative diameters could be between 460 mm to 550 mm.

For purposes of further describing the radiation patterns generated within chamber 100, substrate support 105 is divided into three regions, namely: a central region 20, a periphery region 40, and a mid-radius region 30. These regions are concentric and symmetrical about symmetric axis 115. Central region 20 describes a circular area in the center-most portion of substrate support 105. Periphery region 40 describes an annular area along the outer edge of substrate support 105. Mid-radius region 30 describes an annular area approximately half-way between the center and the edge of substrate support 105 which is bounded by the outer most boundary of central region 20 and the center most boundary of periphery region 40. Although described in relation to a substrate support 105, central region 20, mid-radius region 30 and periphery region 40 are applicable to a substrate 103 disposed on a substrate support 105 as in, for example, during processing operations within chamber 100.

An upper window 107 made of a transparent material such as quartz, for example, encloses the top surface of substrate 103 and substrate support 105 while a lower window 109 encloses the bottom surface thereof. Base plates 111, illustrated in a simplified schematic form, are used to join upper and lower windows 107 and 109 forming a gas-tight joint.

In operation, process and cleaning/purging gases are provided into chamber 100 via ports formed within base plates 111. Gases enter chamber 100 via an inlet port on one side of chamber 100, flow across substrate support 105 and substrate 103 in a substantially laminar flow and then exit via an exhaust port opposite to the inlet port.

A support shaft 117 extends upwardly within the neck 113 of lower window 109 along axis 115 which is attached to and supports the substrate support 105. Shaft 117 and substrate support 105 may be rotated during processing operations by a motor (not shown).

The reactor heater system of chamber 100 comprises a lower heat source 119 and an upper heat source 121. Upper 121 and lower 119 heat sources are positioned adjacent to upper window 107 and lower window 109 covers respectively for the purpose of heating substrate 103 and substrate support 105 during processing operations conducted within chamber 100. Lower heat source 119 comprises an inner array 160 of radiant lamps 127, an outer array 180 of radiant lamps 127, and an intermediate array 170 of radiant lamps 127 disposed between the inner array 160 and outer array 180. Radiant lamps 127 could be, for example, 2 kW tungsten filament infrared bulbs which are about four inches long with a diameter of about 1.25 inches. Alternatively, radiant lamps 127 may be any suitable heating element capable of heating the substrate 103 to a temperature within a range of about 200 degrees Celsius to about 1600 degrees Celsius. Electrical interfacing for radiant lamps 127 is provided by sockets 129. For representative 450 mm substrates, the number of radiant lamps 127 for the inner array 160 used in the chamber 100 of FIG. 1 may be about 8 to about 16, for example 12, the number of radiant lamps 127 for the intermediate array 170 may be about 24 to about 40, for example about 32, and the number of radiant lamps 127 for the outer array 180 may be about 32 to about 52, for example about 44. Inner array 160, intermediate array 170 and outer array 180 are in a concentric, annular arrangement, and each has radiant lamps equally spaced apart around the circumference of the chamber 100.

Lower heat source 119 also includes a plurality of reflectors, such as an outer reflector 145, which provides for mechanical attachment of radiant lamps 127 as well as reflective surface 147 to enhance directivity of radiation generated by radiant lamps 127 within outer array 180. Reflectors may be adapted for the upper heat source 121. For the chamber 100 of FIG. 1, outer reflector 145 could be about 4.5 inches to about 7.2 inches in height and formed from a rigid, thermally durable material such as aluminum, stainless steel or brass. Additionally, the reflective surfaces of outer reflector 145 may be coated with a material having good reflective qualities for radiation such as gold or copper.

Inner array 160 has a smaller diameter than outer array 180. Inner array 160 circumscribes the central portion of substrate support 105 or substrate 103. Outer array 180 circumscribes the periphery of substrate support 105 and substrate 103 and as such has a diameter about as large as or larger than that of both substrate 103 and support 105. Intermediate array 170 circumscribes the periphery of inner array 160 and has a smaller diameter than outer array 180. Inner, intermediate, and outer arrays of radiant lamps 127 are disposed within planes substantially parallel to but vertically disposed from substrate 103 and substrate support 105, creating the radiant energy assembly. In a chamber 100 designed to process substrates having 450 mm diameters, for example, inner array 160 could be disposed about 15-18 inches from substrate support 105 and have a diameter of between about 220 mm to 280 mm. Intermediate array 170 could be disposed about 12-14 inches from substrate support 105 and have a diameter of between about 300 mm to 360 mm. Outer array 180 could be disposed about 8-11 inches from substrate support 105 and have a diameter of between about 380 mm to 480 mm. These diameters and distance between lamp array and substrate support are exemplary and may vary depending upon application.

### Exemplary Liner Assembly

Implementations discussed below describe a liner for use in semiconductor process systems. The liner incorporates a crossflow design including at least 6 zones to allow for greater flow zonality. Further, a temperature sensing device is used in connection with but separate from the liner, allowing for greater ease of exchanging the liners, a more resilient liner and reduced expense. As well, the positioning of the crossflow port off center (e.g., a position which is not the 0 degree position) from the centerline to allow for increased variability in spacing between the zones of flow.

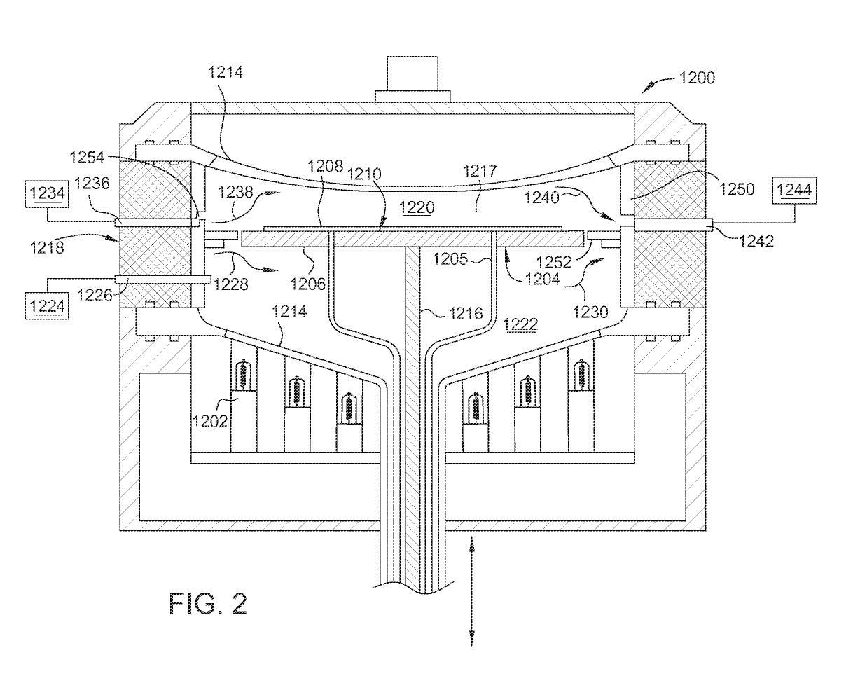

FIG. 2 illustrates a schematic sectional view of a heating process chamber 1200 having a liner assembly 1250, according to another implementation. In one example, this can be a backside heating process chamber. One example of a process chamber that may be adapted to benefit from the implementations described herein is an Epi process chamber, which is available from Applied Materials, Inc., located in Santa Clara, Calif. It is contemplated that other processing chambers, including those from other manufacturers, may be adapted to practice the present implementations.

The process chamber 1200 may be used to process one or more substrates, including the deposition of a material on an upper surface of a substrate 1208. The process chamber 1200 can include a process chamber heating device, such as an array of radiant lamps 1202 for heating, among other components, a back side 1204 of a substrate support 1206 or the back side of the substrate 1208 disposed within the process chamber 1200. The substrate support 1206 may be a disk-like substrate support 1206 as shown, or may be a ring-like substrate support, which supports the substrate from the edge of the substrate or may be a pin-type support which supports the substrate from the bottom by minimal contact posts or pins.

In this implementation, the substrate support 1206 is depicted as located within the process chamber 1200 between an upper dome 1214 and a lower dome 1212. The upper dome 1214 and the lower dome 1212, along with a base ring 1218 that is disposed between the upper dome 1214 and lower dome 1212, can define an internal region of the process chamber 1200. The substrate 1208 can be brought into the process chamber 1200 and positioned onto the substrate support 1206 through a loading port, which is obscured by the substrate support 1206 in the view of FIG. 2.

The base ring 1218 can generally include the loading port, a process gas inlet 1236, and a gas outlet 1242. The base ring 1218 may have a generally oblong shape with the long side on the loading port and the short sides on the process gas inlet 1236 and the gas outlet 1242, respectively. The base ring 1218 may have any desired shape as long as the loading port, the process gas inlet 1236 and the gas outlet 1242 are angularly offset at about 90 degrees with respect to each other. For example, the loading port may be located at a side between the process gas inlet 1236 and the gas outlet 1242, with the process gas inlet 1236 and the gas outlet 1242 disposed at opposing one another on the base ring 1218. In various implementations, the loading port, the process gas inlet 1236 and the gas outlet 1242 are aligned to each other and disposed at substantially the same level with respect to a basis plane of the chamber 1200. Words such as “above”, “below”, “top”, “bottom”, “upper”, “lower”, etc. are not references to absolute directions but are relative to the basis plane of the chamber 1200.

The term “opposite”, as used herein, is defined in mathematical terms such that A is opposite to B with respect to a reference plane P extending between A and B. Opposite is intended generally and thus does not require that A and B be exactly opposite, unless expressly stated.

The substrate support 1206 is shown in an elevated processing position, but may be vertically translated by an actuator (not shown) to a loading position below the processing position to allow lift pins 1205 to contact the lower dome 1212, extend through holes in the substrate support 1206 and along a central shaft 1216, and raise the substrate 1208 from the substrate support 1206. A robot (not shown) may then enter the process chamber 1200 to engage and remove the substrate 1208 therefrom though the loading port. The substrate support 1206 then may be actuated up to the processing position to place the substrate 1208, with its device side 1217 facing up, on a front side 1210 of the substrate support 1206.

The substrate support 1206, while located in the processing position, divides the internal volume of the process chamber 1200 into a processing region 1220 that is above the substrate, and a purge gas region 1222 below the substrate support 1206. The substrate support 1206 can be rotated during processing by the central shaft 1216 to minimize the effect of thermal and process gas flow spatial anomalies within the process chamber 1200 and thus facilitate uniform processing of the substrate 1208. The substrate support 1206 is supported by the central shaft 1216, which moves the substrate 1208 in an up and down direction during loading and unloading, and in some instances, during processing of the substrate 1208. The substrate support 1206 may be formed from silicon carbide or graphite coated with silicon carbide to absorb radiant energy from the lamps 1202 and direct the radiant energy to the substrate 1208.

In general, the central window portion of the upper dome 1214 and the bottom of the lower dome 1212 are formed from an optically transparent material such as quartz. The thickness and the degree of curvature of the upper dome 1214 may be configured to manipulate the uniformity of the flow field in the process chamber.

The lamps 1202 can be disposed adjacent to and beneath the lower dome 1212 in a specified manner around the central shaft 1216 to independently control the temperature at various regions of the substrate 1208 as the process gas passes over, thereby facilitating the deposition of a material onto the upper surface of the substrate 1208. The lamps 1202 may be used to heat the substrate 1208 to a temperature within a range of about 200 degrees Celsius to about 1600 degrees Celsius. While not discussed here in detail, the deposited material may include silicon, doped silicon, germanium, doped germanium, silicon germanium, doped silicon germanium, gallium arsenide, gallium nitride, or aluminum gallium nitride.

Process gas supplied from a process gas supply source 1234 is introduced into the processing region 1220 through a process gas inlet 1236 formed in the sidewall of the base ring 1218. The process gas inlet 1236 connects to the process gas region through a plurality of gas passages 1254 formed through the liner assembly 1250. The process gas inlet 1236, the liner assembly 1250, or combinations thereof, are configured to direct the process gas in a direction which can be generally radially inward. During the film formation process, the substrate support 1206 is located in the processing position, which can be adjacent to and at about the same elevation as the process gas inlet 1236, allowing the process gas to flow up and round along flow path 1238 across the upper surface of the substrate 1208. The process gas exits the processing region 1220 (along the flow path 1240) through a gas outlet 1242 located on the opposite side of the process chamber 1200 as the process gas inlet 1236. Removal of the process gas through the gas outlet 1242 may be facilitated by a vacuum pump 1244 coupled thereto.

Purge gas supplied from a purge gas source 1224 is introduced to the purge gas region 1222 through a purge gas inlet 1226 formed in the sidewall of the base ring 1218. The purge gas inlet 1226 connects to the process gas region through the liner assembly 1250. The purge gas inlet 1226 is disposed at an elevation below the process gas inlet 1236. If the circular shield 1252 is used, the circular shield 1252 may be disposed between the process gas inlet 1236 and the purge gas inlet 1226. In either case, the purge gas inlet 1226 is configured to direct the purge gas in a generally radially inward direction. If desired, the purge gas inlet 1226 may be configured to direct the purge gas in an upward direction. During the film formation process, the substrate support 1206 is located at a position such that the purge gas flows down and round along flow path 1228 across back side 1204 of the substrate support 1206. Without being bound by any particular theory, the flowing of the purge gas is believed to prevent or substantially avoid the flow of the process gas from entering into the purge gas region 1222, or to reduce diffusion of the process gas entering the purge gas region 1222 (i.e., the region under the substrate support 1206). The purge gas exits the purge gas region 1222 (along flow path 1230) and is exhausted out of the process chamber through the gas outlet 1242 located on the opposite side of the process chamber 1200 as the purge gas inlet 1226.

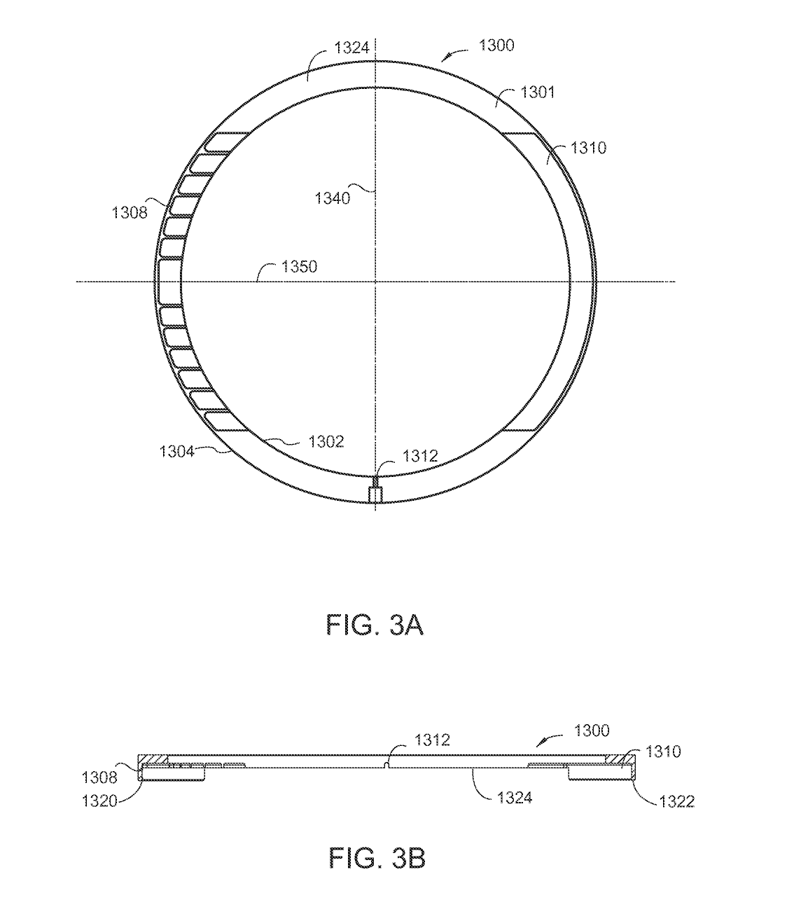

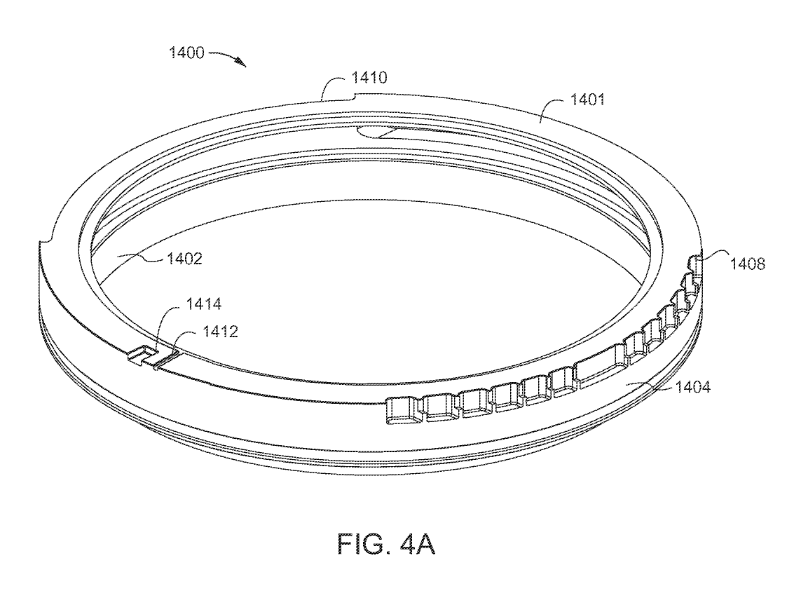

The liner assembly 1250 may be disposed within or surrounded by an inner circumference of the base ring 1218. The liner assembly 1250 may be formed from a quartz material and generally shields the walls of the process chamber 1200 from conditions in the processing region 1220 and purge gas region 1222. The walls, which may be metallic, may react with precursors and cause contamination in the processing volume. An opening may be disposed through the liner assembly 1250 and aligned with the loading port to allow for passage of the substrate 1208. While the liner assembly 1250 is shown as a single piece, it is contemplated that the liner assembly 1250 may be formed from multiple pieces. The liner assembly 1250 shown in FIG. 2 is composed of an upper liner 200 and a lower liner 1400, which are described in more detail in FIGS. 3 and 4.

FIG. 3A depicts a top view of an upper liner 1300, according to implementations described herein. The upper liner 1300 includes an upper body 1301 having an inner surface 1302 and an outer surface 1304 opposite the inner surface 1302. A plurality of upper inlets 1308 are formed through the outer surface 1304 of the body 1301. An exhaust port 1310 is formed opposite the plurality of upper inlets 1308. An upper crossflow port 1312 is formed between the plurality of upper inlets 1308 and the exhaust port 1310.

The plurality of upper inlets 1308 may be described as recesses or grooves formed in the upper body 1301. Shown here, the plurality of upper inlets 1308 are substantially rectangular and parallel to one another. The plurality of upper inlets 1308 may vary in quantity, size and shape, based on desires of the user, flow dynamics, or other parameters. Shown here, thirteen (13) upper inlets 1308 are formed in the upper body 1301. The plurality of upper inlets 1308 can be configured to create a plurality of flow zones in the processing region 1220.

FIG. 3B depicts a side view of the upper liner 1300, according to the implementations of FIG. 3A. The plurality of upper inlets 1308 delivers a gas flow from the process gas supply source 1234 to the processing region 1220. FIG. 3B further shows a plurality of upper protrusions, such as an upper inlet protrusion 1320 and an exhaust protrusion 1322. The upper inlet protrusion 1320 and an exhaust protrusion 1322 may be accompanied by further protrusions formed at any position of the upper liner. Further, the upper inlet protrusion 1320, the exhaust protrusion 1322 or both may be excluded or replaced with upper protrusions at different positions on the upper body 1301. The upper inlet protrusion 1320 and the exhaust protrusion 1322 assist with proper positioning of the upper liner 1300 in connection with the lower liner 1400, described below.

FIGS. 4A and 4B depict a lower liner 1400 according to one implementation. The lower liner 1400 includes a lower body 1401 with an inner surface 1402 and an outer surface 1404. The inner surface 1402, in conjunction with the inner surface 1302, form the boundaries of the processing region 1220 and the purge gas region 1222. A plurality of lower inlets 1408 are formed through the outer surface 1404 of the body 1401. Gas supplied from the process gas supply source 1234 is introduced into the processing region 1220 through the plurality of lower inlets 1408.

The plurality of lower inlets 1408 are positioned radially through the exterior of the lower body 1401. The plurality of lower inlets 1408 can deliver one or more individual gas flows. Shown here, thirteen (13) lower inlets 1408 are formed in the lower body 1401. However, more or fewer inlets may be used in one or more implementations. The lower inlets may be positioned and oriented to create multiple flow zones. The flow zones are regions of differing gas flow as delivered through the lower inlets 1408 and the upper inlets 1308. By creating more zones, the gas delivery over the substrate is more tunable than with fewer flow zones.

The plurality of lower inlets 1408 may be configured to provide individual gas flows with varied parameters, such as velocity, density, or composition. The plurality of lower inlets 1408 are configured to direct the process gas in a generally radially inward direction, with the gas being delivered to a central area of the processing region. Each of the plurality of lower inlets 1408 may be used to adjust one or more parameters, such as velocity, density, direction and location, of the gas from the process gas supply source 1234. The plurality of lower inlets 1408 are positioned across from an exhaust port 1410 and at least 25 degrees apart from a crossflow port 1412. In one implementation, the crossflow port is position at the 0 degree position as measured from a bisecting line 1340. The plurality of lower inlets 1408 can be positioned at 90 degrees as measured between a midline 1350 and the bisecting line 1340. The exhaust port 1410 can be positioned at 270 degrees as measured between the midline 1350 and the bisecting line 1340.

Shown in FIG. 4B is the lower connecting surface 1420 of the lower liner 1400. The lower connecting surface 1420 provides a receiving surface for the upper connecting surface 1324. As such, the lower connecting surface 1420 may have grooves, flat regions or other areas such that the lower connecting surface 1420 can properly mate with the upper connecting surface 1324. Shown here, an inlet groove 1424 is formed through the lower connecting surface 1420 at the plurality of lower inlets 1408. Further shown is a lower surface 1422, which contacts the chamber and supports the lower liner 1400.

The lower liner 1400 and the upper liner 1300 are combined to create the liner assembly 1250. In one implementation, an upper connecting surface 1324 is placed in connection with the lower connecting surface 1420. The upper connecting surface 1324 forms a seal with at least a portion of the lower connecting surface 1420. When the upper connecting surface 1324 is placed in connection with lower connecting surface 1420, the plurality of lower inlets 1408 extend upward to deliver the gas flow through the plurality of upper inlets 1308 of the upper liner 1300. Thus the gas flow is redirected to the processing region 1220. Though shown with an equal number of lower inlets 1408 and upper inlets 1308, the number and positioning of the lower inlets 1408 may differ from shown or comparatively to the upper inlets 1308.

The upper crossflow port 1312 combines with the lower crossflow port 1412 to create a crossflow port. The crossflow port can deliver a gas flow which is substantially perpendicular to the flow of gas from the plurality of gas passages 1254. The position of the crossflow port may be coplanar with the plurality of upper inlets 1308, the upper crossflow port 1312, the lower crossflow port 1412, the upper exhaust port 1310, the lower crossflow port 1412 or combinations thereof. The orientation of the crossflow port may be substantially perpendicular to and intersecting with the flow from the plurality of gas passages 1254 (e.g., perpendicular in the x and y plane and intersecting in the z plane). In another implementation, the crossflow port is oriented to deliver a gas out of plane from the gas flow from the plurality of gas passages 1254 (e.g., perpendicular in the x and y plane and not intersecting in the z plane).

A thermal sensing port 1414 can be positioned in the lower body 1401. The thermal sensing port 1414 can house a thermal sensing device for the process chamber 1200, such as a thermocouple. The thermal sensing port 1414 allows for temperature measurement during processing such that temperature of the substrate, and deposition from the process gases, can be fine-tuned. The thermal sensing port 1414 can be positioned near the lower crossflow port 1412. In one implementation, the thermal sensing port 1414 is positioned at the 5 degree position as measured from a bisecting line 1440, shown in FIG. 4B, at the outer circumference. It is believed that the combination of the thermal sensing port 1414 and the crossflow port 1412 can create abnormal wear. By separating the thermal sensing port 1414 from the crossflow port 1412, abnormal wear related to the combination may be avoided.

During processing, the substrate support 1204 may be located in the processing position, which is adjacent to and at about the same elevation as the plurality of gas passages, allowing the gas to flow up and round along flow path across the upper surface of the substrate support. The crossflow port 1412 delivers a second gas flow across the flow of the plurality of gas passages such that the second gas flow intersects with at least one of the flow regions created by the plurality of gas passages. The process gas exits the processing region through the exhaust port 1410 formed through the body 1401. Removal of the process gas through the exhaust port 1410 may be facilitated by a vacuum pump (not shown) coupled thereto. As the plurality of gas passages and the exhaust port 1410 are aligned to each other and disposed approximately at the same elevation, it is believed that such a parallel arrangement will enable a generally planar, uniform gas flow across the substrate. Further, radial uniformity may be provided by the rotation of the substrate through the substrate support.

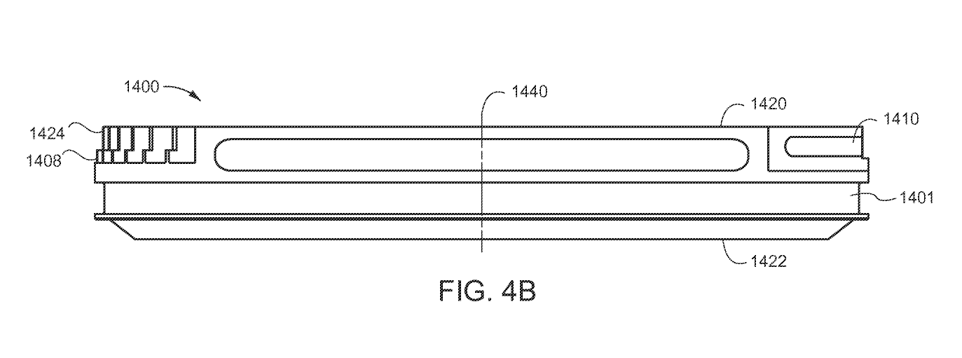

FIG. 5 depicts a lower liner 1500 according to another implementation. The lower liner 1500 includes a lower body 1501 with an inner surface 1502 and an outer surface 1504. As above, the inner surface 1502, in conjunction with the inner surface 1302, form the boundaries of the processing region 1220 and the purge gas region 1222. A plurality of lower inlets 1508 are formed through the outer surface 1504 of the lower body 1501. The lower liner 1500 further comprises an exhaust port 1510, a lower crossflow port 1512, and a thermal sensing port 1514. The thermal sensing port 1514 can be positioned near the lower crossflow port 1512.

In this implementation, the plurality of lower inlets 1508 has two separate rows. Two separate gas flows, as delivered through the plurality of lower inlets 1508, allow two separate gas flows to be combined prior to delivery to the processing region 1220. In this implementation, the first row and the second row feed into the same channel created in combination with the upper liner. By combining two gas flows through gas passages 1254 of the liner assembly 1250, the temperature of the gases can be modulated prior to delivery to the process chamber, complex chemistries can be activated and delivered without negatively affecting the substrate and changes in flow dynamics in the process chamber can be avoided.

The liner assembly described herein allows for finer control of deposition uniformity for both current substrate sizes, such as a 300 mm diameter, and larger, such as 450 mm diameter. The flow zones allow for finer control of deposition in specific regions of the substrate.

### Exemplary Inject Inserts

Implementations disclosed below describe an inject insert for use in semiconductor process systems. The inject insert connects with and incorporates at least 6 zones. The newly created zones may be either single or multi-layered. The zones created by the inject insert allow for greater flow control within the process chamber. By increasing flow control, more uniform epitaxial growth can be achieved while reducing process gas waste and decreasing production time.

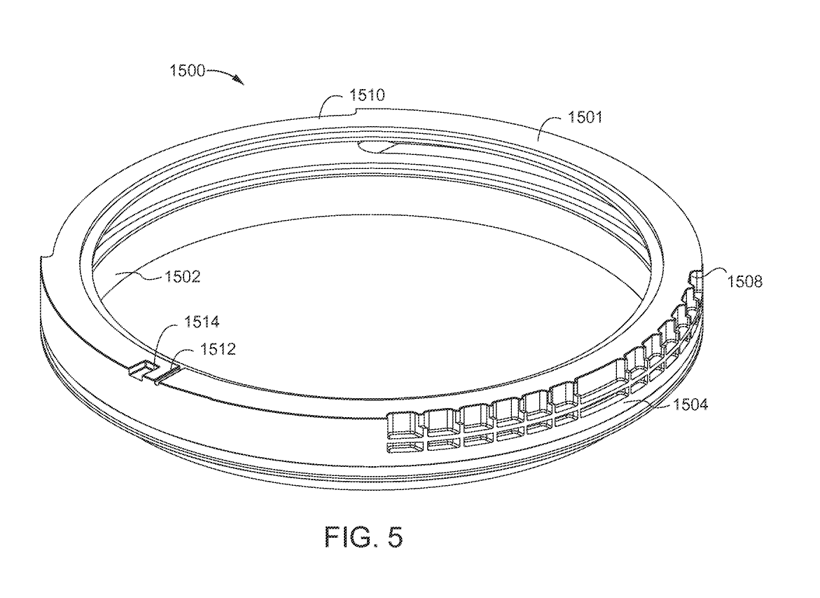

FIGS. 6A and 6B depict a liner assembly 1600 with an inject insert 1620 according to implementations described herein. FIG. 6A depicts a top view of the inject insert 1620 in connection with a liner assembly 1600. FIG. 6B depicts a side view of the inject insert 1620. The liner assembly 1600 includes a liner body 1602 with an inner surface 1604 and an outer surface 1606. The inner surface 1604 forms the boundaries of a processing region, such as processing region 1220 described with reference to FIG. 2. A plurality of liner inlets 1608, which are depicted as dashed line circles, are formed through the inner surface 1604 and outer surface 1606 of the liner body 1602. The inject insert 1620, shown here with two inject inserts 1620, is fluidly connected with the plurality of liner inlets 1608. Gas supplied from a gas supply source is introduced into the processing region, through the inject insert 1620 and then through the plurality of liner inlets 1608, whereby the plurality of liner inlets 1608 can deliver one or more individual gas flows. The inject insert 1620, plurality of liner inlets 1608 or both may be configured to provide individual gas flows with varied parameters, such as velocity, density, or composition. The plurality of liner inlets 1608 are configured to direct the process gas in a generally radially inward direction, with the gas being delivered to a central area of the processing region. Each of the plurality of liner inlets 1608 and the inject insert 1620 may be used, individually or in combination, to adjust one or more parameters, such as velocity, density, direction and location, of the gas from the gas supply source.

The inject insert 1620 can be formed from a single piece of metal, ceramic or otherwise inert composition, such as aluminum or quartz. The inject insert 1620 can have a substantially planar upper surface 1622 and a substantially planar lower surface 1624. The inject insert 1620 can have a number of inject ports 1626 formed therein. The end portions of the inject insert 1620 are shown here, with the middle portions omitted for simplicity. In this implementation, the inject insert 1620 is depicted as having seven (7) inject ports 1626. The inject ports 1626 may be of any shape or size, such that the flow rate, flow velocity and other flow parameters may be controlled. Further, multiple inject ports 1626 may connect with any number of the plurality of liner inlets 1608. In one implementation, a single port of the plurality of liner inlets 1608 is served by more than one of the inject ports 1626. In another implementation, a multiple ports of the plurality of liner inlets 1608 is served by a single port of the inject ports 1626. The inject insert 1620 has a connecting surface 1628. The connecting surface 1628 may have a surface curvature such that the inject ports 1626 penetrating through the inject insert 1620 are fluidly sealed to the plurality of liner inlets 1608. The inject insert 1620 may have an exterior surface 1630. The exterior surface 1630 may be configured to connect to one or more gas lines 1701 or other gas delivering device.

The inject ports 1626 and the liner inlets 1608 create at least a first zone, a second zone and a third zone. The first zone has a first number of passages. The second zone has a second number of passages, the second number of passages being different from the first number of passages. The third zone has a third number of passages, the third number of passages being different from the first number of passages and the second number of passages. Larger substrates, due to their increased surface area, require tighter control of process parameters. Thus, by increasing the number of zones, the area that is controlled by a single zone is decreased allowing for finer tuning of process parameters.

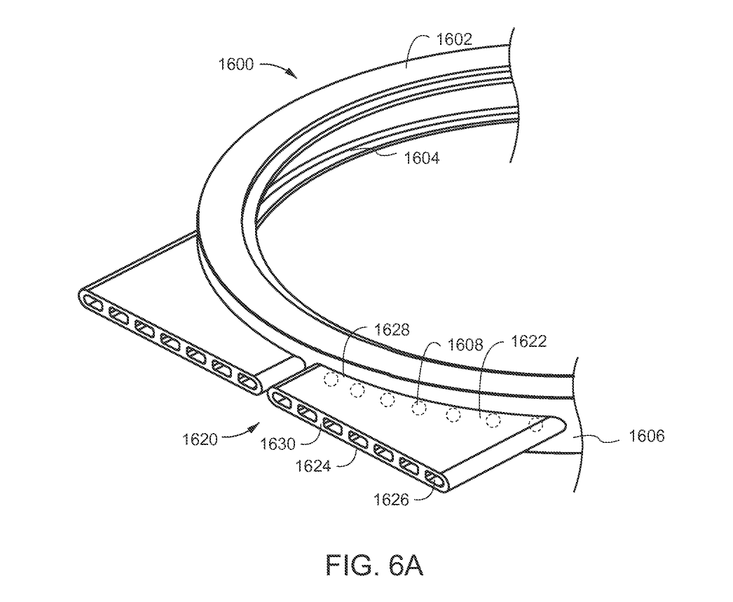

FIG. 7 depicts a cutaway overhead view of an inject insert 1700, according to one implementation. The inject insert 1700 may have the same or a similar composition to the inject insert 1620 described with reference to FIGS. 6A and 6B. The inject insert 1700 has a plurality of inject ports 1726 formed therein, such as seven inject ports 1726. As shown with relation to inject insert 1620, the end portions of the inject insert 1700 are shown here, with the middle portions omitted for simplicity. The inject insert 1700 can have one or more multi-connect gas lines, shown here as first multi-connect gas line 1702, second multi-connect gas line 1704 and third multi-connect gas line 1706. The multi-connect gas lines 1702, 1704 and 1706 are in connection with more than one of the plurality of inject ports 1726 (also referred to as the connected ports).

The multi connect gas lines 1702, 1704 and 1706 can deliver either different gases or gases under differing conditions. In one implementation, the first multi connect gas line 1702 delivers a first gas to the connected ports, the second multi connect gas line 1704 delivers a second gas to the connected ports and the third multi connect gas line 1702 delivers a third gas to the connected ports. The first gas, the second gas and the third gas can be different gases from one another. In another implementation, the first multi connect gas line 1702 delivers a gas to the connected ports at a first pressure and/or a first temperature, the second multi connect gas line 1704 delivers a gas to the connected ports at a second pressure and/or a second temperature, and the third multi connect gas line 1702 delivers a gas to the connected ports at a third pressure and/or a third temperature. The first pressure, second pressure and the third pressure may be different from one another. As well, the first temperature, second temperature and the third temperature may be different from one another. Further any number of inject ports 1726 may be connected to any number of multi-connect gas lines. In further implementations, the one or more gas lines 1701 and/or the multi-connect gas lines 1702, 1704 and 1706 may connect with the same inject port 1726.

Though one or more of the inject ports 1726 are shown as connected through the one or more gas lines 1701 and the multi-connect gas lines 1702, 1704 and 1706, the inject ports 1726 may be interconnected within the inject insert 1700 such that one or more of the multi-connect gas lines 1702, 1704 and 1706 is unnecessary. In this case, a group of the inject ports 1726 can branch internally to the inject insert 1700, shown by a branch 1730, such that the group of the inject ports 1726 receive gas from a single gas line 1701.

The inject insert 1700 can further include a plurality of inject inlets, shown here as inject inlets 1708a-1708g. The inject inlets 1708a-1708g may be approximately equally spaced and positioned in the inject insert 1700. The inject inlets 1708a-1708g may have a varying width such that the inject inlet 1708a-1708g delivers a differing volume of gas at a proportionally changed velocity. When delivering gas through two inject ports 1726 at a standard pressure, an increased width is expected to deliver gas to the processing region at a decreased velocity but higher volume than a standard width. Under the same conditions as above, a decreased width is expected to deliver gas to the processing region at an increased velocity but lower volume than a standard width.

Shown here, inject inlet 1708a has a width 1712a which is increased as compared to the width 1712c of the inject port 1726. Further, the inject inlet 1708a has a graded increase, creating the appearance of a cone. Shown here, the increase of the width 1712a of the inject inlet 1708a results from a graded increase of 5 degrees from a center line 1710, as noted by the dashed line extending outward from the related inject port 1726. The graded increase may be more or less than 5 degrees. Further, a graded increase is not necessary for the formation of an increased in the width 1712a. In one implementation, the width 1712a is simply increased at a point prior to the inject inlet 1708a forming a slightly larger cylinder in the inject port 1726.

Though the center line 1710 is only described with reference to the inject port 1726, it is understood that all bisymmetrical objects or formations as described herein have a center line. Further, though the center line 1710 is only shown with relationship to inject inlet 1708a, it is understood that each of the inject inlets 1708a-1708g have a related center line 1710 which bisects each of the respective inject ports 1726.

In another example, the inject inlet 1708b has a width 1712b which is decreased as compared to the width 1712c of the inject ports 1726. As above, the inject inlet 1708b has a graded decrease, creating the appearance of an inverted cone. Shown here, the decreased width 1712b of the inject inlet 1708b is formed from a graded decrease of 5 degrees from the center line 1710, as noted by the dashed line extending inward from the related inject port 1726. The graded decrease may be more or less than 5 degrees.

Though the increased width 1712a, the decreased width 1712b, and the related graded increase and decrease are shown as symmetrical to the center line 1710, this is not intended to be limiting of implementations described herein. A change in size and shape can be created with full freedom of position and rotation such that the gas can be delivered in any direction and at any angle desired by the end user. Further, the liner inlets 1608 of FIG. 6A and 6B may have a design which either compliments or replicates the designs described with reference to inject inlets 1708a-1708g.

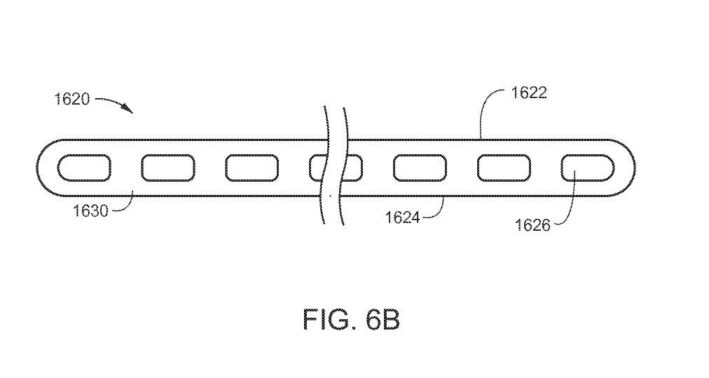

FIG. 8 depicts a side view of a multi-tier inject insert 1800, according to one implementation. The multi-tier inject insert 1800, shown here with two rows of inject ports 1826, can have more than one row of inject ports 1826 such that gas can be delivered to the processing region more uniformly. As shown with relation to inject insert 1620, the end portions of the inject insert 1800 are shown here, with the middle portions omitted for simplicity. The multi-tier inject insert 1800 can have a substantially planar upper surface 1822 and a substantially planar lower surface 1824. The multi-tier inject insert 1800 can have a number of inject ports 1826 formed therein per row. In this implementation, the multi-tier inject insert 1800 is depicted as having fourteen (14) inject ports 1826. In this implementation, the number or shape of each of the inject ports 1826 used in each of the corresponding rows may be of varying shapes, sizes and positions.

Further, multiple inject ports 1826 may connect with any number of the plurality of inject inlets. The inject inlets described with reference to FIG. 8 are substantially similar to the inject inlets 1708 described with reference to FIG. 7. The multi-tier inject insert 1800 has a connecting surface 1828. The connecting surface 1828 may have a surface curvature such that the inject ports 1826 penetrating through the multi-tier inject insert 1800 are fluidly sealed to the upper liner and the lower liner, described below. The multi-tier inject insert 1800 has an exterior surface 1830 which may be configured to connect to a gas line as described in FIG. 7.

Tight control of both chemistry and gas flow is required for current and next generation semiconductor devices. Using the implementations described above, control of both of the delivery of gas to the inject ports and flow of the gas from the inject ports through the inject inlets can be increased, leading to an increased control of process parameters for a majority of the substrate. Increased control of process parameters, including control of the velocity of the gases delivered to the chamber and the subsequent zone formation, will lead to improved epitaxial deposition and reduced product waste among other benefits.

### Exemplary Substrate Support and Preheat Ring

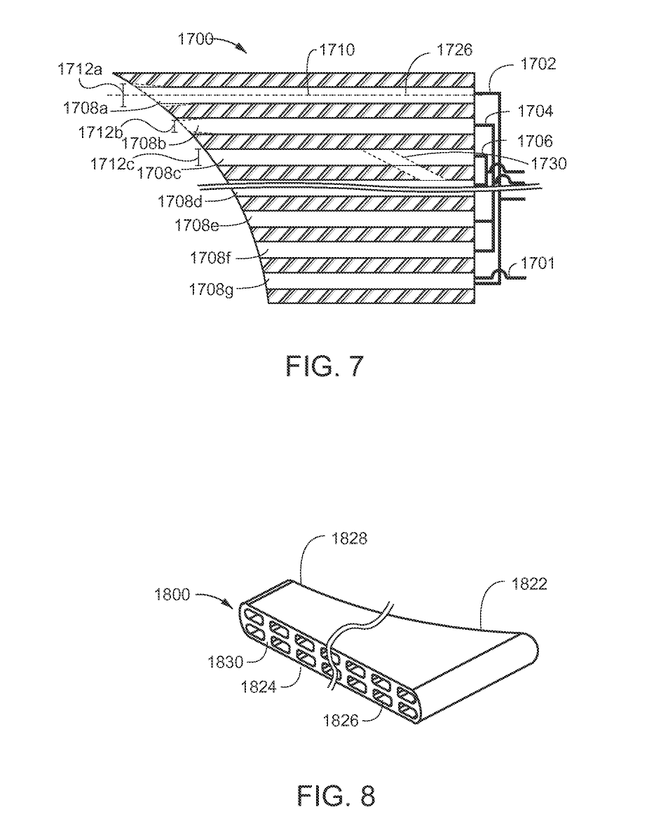

FIG. 9 is a schematic isometric view of a substrate support 1900 according to implementations described herein. The substrate support 1900 includes an outer peripheral edge 1905 circumscribing a recessed pocket 1910 where a substrate may be supported. The substrate support 1900 may be positioned in a semiconductor process chamber, such as a chemical vapor deposition chamber or an epitaxial deposition chamber. One exemplary process chamber that may be used to practice implementations of the present disclosure is illustrated in FIG. 1. The recessed pocket 1910 is sized to receive the majority of the substrate. The recessed pocket 1910 may include a surface 2000 that is recessed from the outer peripheral edge 1905. The pocket 1910 thus prevents the substrate from slipping out during processing. The substrate support 1900 may be an annular plate made of a ceramic material or a graphite material, such as graphite that may be coated with silicon carbide. Lift pin holes 1903 are shown in the pocket 1910.

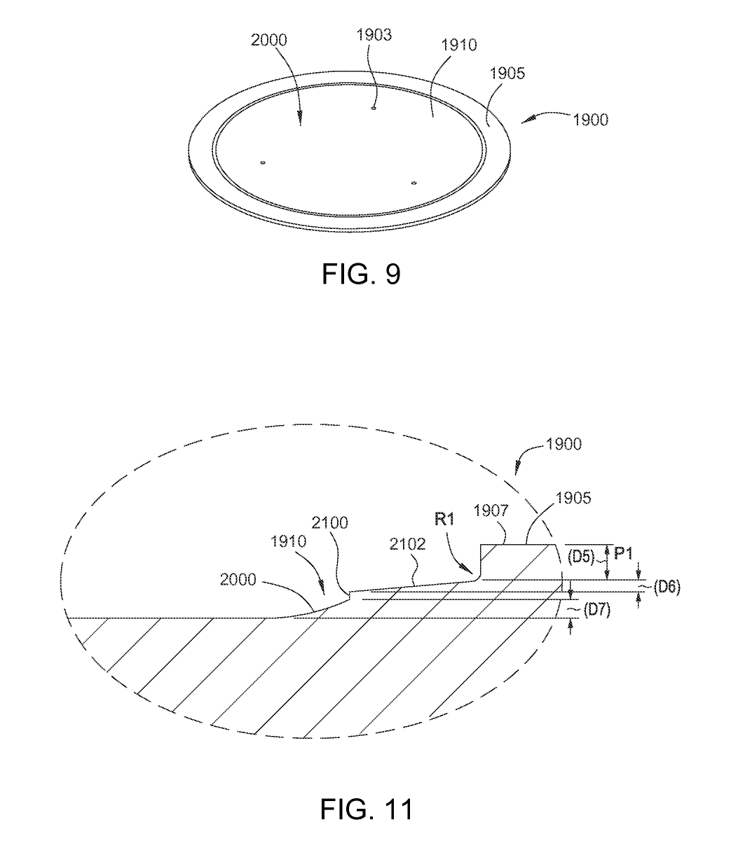

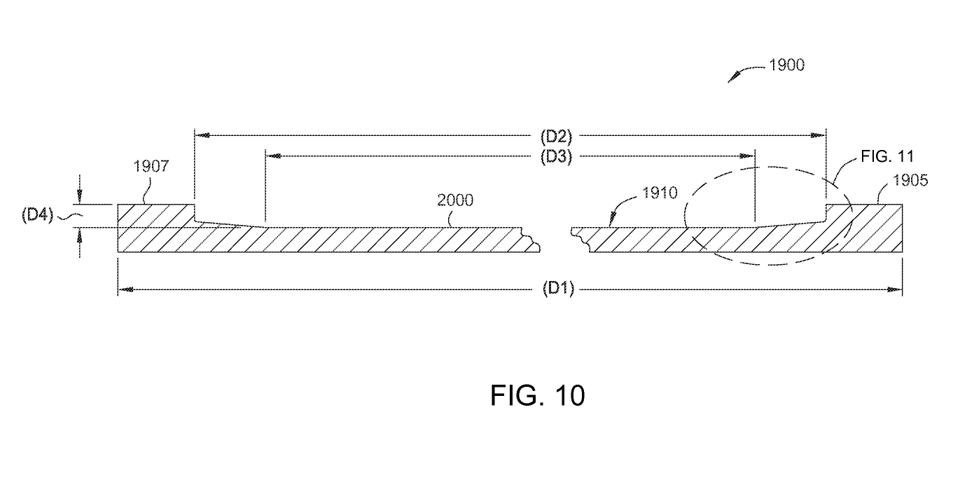

FIG. 10 is a side cross-sectional view of the substrate support 1900 of FIG. 9. The substrate support 1900 includes a first dimension D1 measuring from an outer diameter of the substrate support 1900. The outer diameter of the substrate support 1900 is less than an inner circumference of the semiconductor process chamber, such as the process chamber of FIG. 1. The first dimension D1 is greater than a second dimension D2 of the pocket 1910, which is measured from an inner diameter of the outer peripheral edge 1905. The substrate support 1900 may include a ledge 2100 (see FIG. 11) disposed between an outer diameter of the surface 2000 and the inner diameter of the outer peripheral edge 1905. The pocket 1910 also includes a third dimension D3 measuring from an inner diameter of the ledge 2100. The third dimension D3 is less than the second dimension D2. Each of the dimensions D1, D2 and D3 may be diameters of the substrate support 1900. In one implementation, the third dimension D3 is about 90% to about 97% of the second dimension D2. The second dimension D2 is about 75% to about 90% of the first diameter D1. For a 450 mm substrate, the first dimension D1 may be about 500 mm to about 560 mm, such as about 520 mm to about 540 mm, for example about 535 mm. The pocket 1910 (i.e., the dimension D2 and/or the dimension D3) may be sized to receive a 450 mm substrate, in one implementation.

A depth D4 of the surface 2000 may be about 1 mm to about 2 mm from a top surface 1907 of the outer peripheral edge 1905. In some implementations, the surface 2000 is slightly concave to prevent portions of an underside of a sagging substrate from contacting the substrate support during processing. The surface 2000 may include a pocket surface radius (spherical radius) of about 34,000 mm to about 35,000 mm, such as about 34,200 mm to about 34,300 mm. The pocket surface radius may be utilized to prevent contact between a substrate surface and at least a portion of the surface 2000 during processing, even when the substrate is bowed. The height and/or the pocket surface radius of the recessed pocket 1910 are variable based on the thickness of the substrate supported by the substrate support 1900.

FIG. 11 is an enlarged cross-sectional view showing a portion of the substrate support of FIG. 10. The outer peripheral edge 1905 protrudes from an upper surface of the substrate support. In some implementations, an angled support surface 2102, which serves as part of a supporting surface for a substrate, is disposed between the pocket 1910 and the outer peripheral edge 1905. Particularly, the angled support surface 2102 is between the inner diameter of the outer peripheral edge 1905 (i.e., dimension D2) and the inner diameter of the ledge 2100 (i.e., dimension D3). The angled support surface 2102 can reduce a contacting surface area between a substrate and the substrate support 1900 when an edge of the substrate is supported by the angled support surface 2102. In one implementation, the top surface 1907 of the outer peripheral edge 1905 is higher than the angled support surface 2102 by a dimension D5, which may be less than about 3 mm, such as about 0.6 mm to about 1.2 mm, for example about 0.8 mm.

In one implementation, a fillet radius “R1” is formed at an interface where the outer peripheral edge 1905 and the angled support surface 2102 meet. The fillet radius R1 may be a continuously curved concave. In various implementations, the fillet radius “R1” ranges between about 0.1 inches and about 0.5 inches, such as about 0.15 inches and about 0.2 inches.

The angled support surface 2102 may be inclined with respect to a horizontal surface, for example the top surface 1907 of the outer peripheral edge 1905. The angled support surface 2102 may be angled between about 1 degree to about 10 degrees, such as between about 2 degrees to about 6 degrees. Varying the slope or dimensions of the angled support surface 2102 can control the size of a gap between the bottom of the substrate and the surface 2000 of the pocket 1910, or the height of the bottom of the substrate relative to the pocket 1910. In the implementation shown in FIG. 11, the cross-sectional view shows the angled support surface 2102 extending radially inward from the fillet radius R1 toward the surface 2000 by a height shown as a dimension D6, which may be less than about 1 mm. The angled support surface 2102 ends at the outer diameter of the surface 2000. The surface 2000 may be recessed from the bottom of the ledge 2100 by a height shown as a dimension D7. Dimension D7 may be greater than the dimension D6. In one implementation, the dimension D6 is about 65% to about 85% of the dimension D7, for example about 77% of the dimension D7. In other implementations, the dimension D7 is about a 30% increase from the dimension D6. In one example, dimension D6 is about 0.05 mm to about 0.15 mm, for example about 0.1 mm. In some implementations, the top surface 1907 may be roughened to about 5 Ra to about 7 Ra.

The substrate support 1900 with features described herein (e.g., angled support surface and pocket surface radius) has been tested and results show good heat transfer between a substrate and the surface 2000 without contact between the substrate and the surface 2000. Utilization of the ledge 2100 provides heat transfer by a minimum contact between the substrate and the angled support surface 2102.

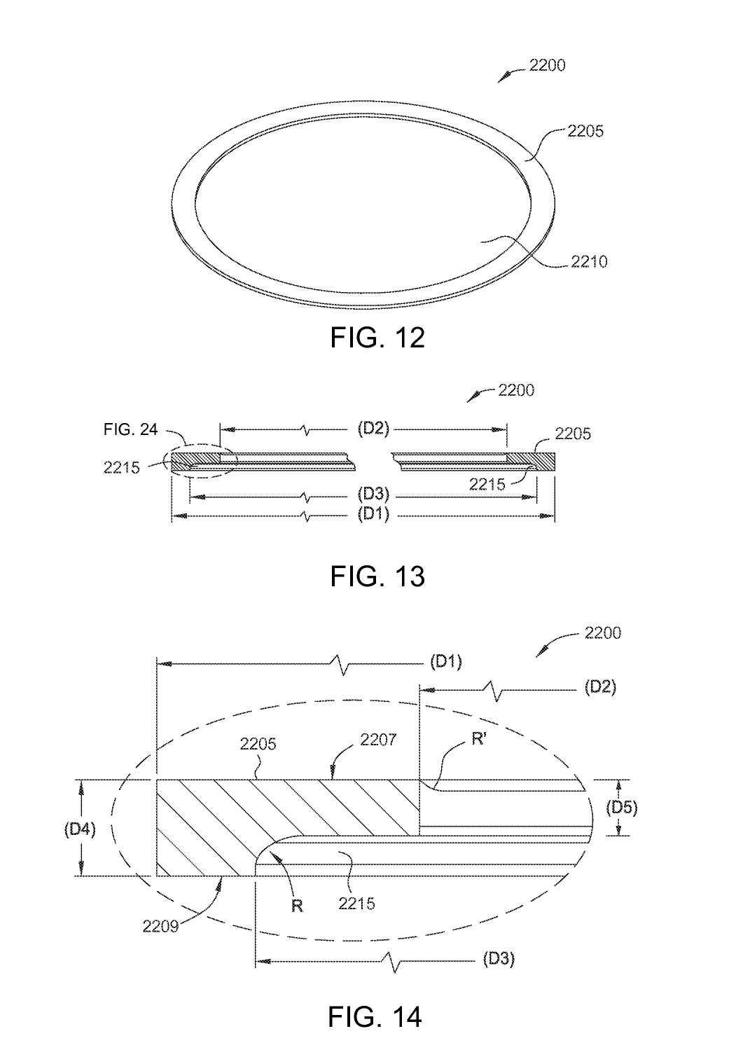

FIG. 12 is a schematic isometric view of a pre-heat ring 2200 according to implementations described herein. The pre-heat ring 2200 may be positioned in a semiconductor process chamber, such as such as a chemical vapor deposition chamber or an epitaxial deposition chamber. Particularly, the pre-heat ring 2200 is configured to be disposed around the periphery of the substrate support (e.g., the substrate support 1900 of FIGS. 9-11) while the substrate support is in a processing position. One exemplary process chamber that may be used to practice implementations of the present disclosure is illustrated in FIG. 1. The pre-heat ring 2200 includes an outer peripheral edge 2205 circumscribing an opening 2210 where a substrate support, such as the substrate support 1900 of FIGS. 9-11, may be positioned. The pre-heat ring 2200 includes a circular body made of a ceramic material or a carbon material, such as graphite that may be coated with silicon carbide.

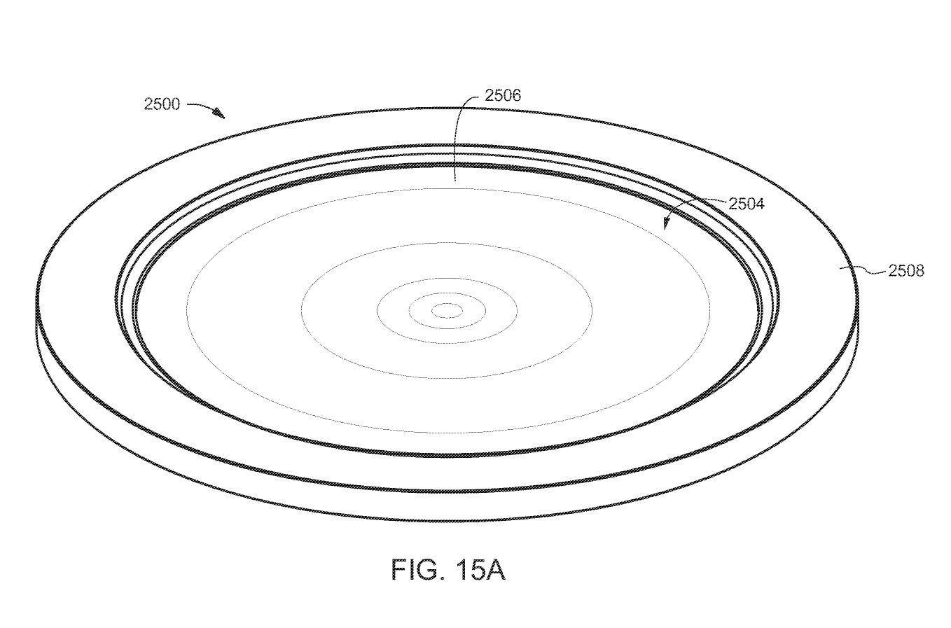

FIG. 13 is a side cross-sectional view of the pre-heat ring 2200 of FIG. 12. The pre-heat ring 2200 includes a first dimension D1 measuring from an outer diameter of the outer peripheral edge 2205, and a second dimension D2 measuring from an inner diameter of the outer peripheral edge 2205. The outer diameter of the outer peripheral edge has a circumference less than a circumference of the semiconductor process chamber, such as the process chamber of FIG. 1. The second dimension D2 may be substantially equal to a diameter of the opening 2210. The first dimension D1 is less than an inner circumference of the semiconductor process chamber, such as the process chamber of FIG. 1. The pre-heat ring 2200 also includes a recess 2215 formed in a bottom surface (e.g., bottom surface 2209) of the outer peripheral edge 2205. The recess 2215 includes a third dimension D3 measuring from an outer diameter of the recess 1945. The third dimension D3 is less than the first dimension D1 but greater than the second dimension D2. Each of the dimensions D1, D2 and D3 may be diameters of the pre-heat ring 2200. The recess 2215 may be utilized to contact a substrate support, such as the substrate support 1900 as described with reference to FIG. 9, in use, and the third dimension D3 may be substantially equal to or slightly larger than an outer diameter of the substrate support (e.g., the dimension D1 of FIG. 10).

In one implementation, the dimension D3 is about 90% to about 98% of the first dimension D1, for example about 94% to about 96% of the first dimension D1, and the second dimension D2 is about 80% to about 90% of the first dimension D1, for example about 84% to about 87% of the first dimension D1. For a 450 mm substrate, the first dimension D1 may be about 605 mm to about 630 mm, such as about 615 mm to about 625 mm, for example 620 mm. The pre-heat ring 2200 may be sized to be utilized in the processing of a 450 mm substrate, in one implementation.

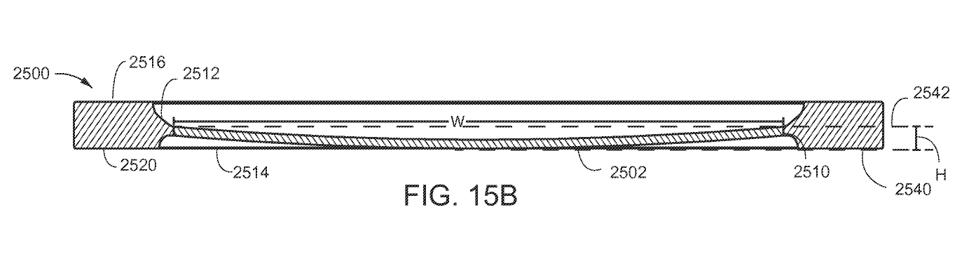

FIG. 14 is an enlarged cross-sectional view of the pre-heat ring 2200 of FIG. 13. The pre-heat ring 2200, which is a circular body, may include a first thickness (i.e., outer thickness) shown as dimension D4 and a second thickness (i.e., inner thickness) shown as dimension D5. Dimension D4 is greater than the dimension D5. In one implementation, the dimension D5 is about 75% to about 86% of the dimension D4, for example about 81% of the dimension D4. The outer peripheral edge 2205 of the pre-heat ring 2200 includes a top surface 2207 and a bottom surface 2209 that are substantially parallel (i.e., parallelism of less than about 1.0 mm). The top surface 2207 extends a first radial width inwardly from an edge of the pre-heat ring 2200 to the opening 2210, while the bottom surface 2209 extends a second radial width inwardly from the edge of the pre-heat ring 2200 to the recess 2215. The first radial width is greater than the second radial width. In one implementation, the first radial width is about 5 mm to about 20 mm, such as about 8 mm to about 16 mm, for example about 10 mm. At least the bottom surface 2209 includes a flatness of less than about 1.0 mm, in some implementations. A fillet radius “R” is formed at a corner of the recess 2215. A chamfer “R′” may also be formed on corners of the pre-heat ring 2200, e.g., an interface where an outer edge of the opening 2210 and an inner edge of the outer peripheral edge 2205 meet. One or both of R and R′ may be about less than 0.5 mm in one implementation. In one implementation, the dimension D5 is about 6.00 mm.

The radial width of the outer peripheral edge 2205 is utilized to absorb heat from energy sources, such as radiant lamps 127 shown in FIG. 1. Precursor gases are typically configured to flow across the outer peripheral edge 2205 in a manner substantially parallel to the top surface 2207 and the gases are pre-heated prior to reaching a substrate positioned on a substrate support, such as the substrate support 1900 of FIGS. 9-11, in the processing chamber. The pre-heat ring 2200 has been tested and results show that the flow of the precursor gas can establish a laminar-flow boundary layer over and across the top surface 2207 of the pre-heat ring 2200. Particularly, the boundary layer, which improves heat transfer from the pre-heat ring 2200 to the precursor gas, is fully developed before the precursor gas reaching the substrate. As a result, the precursor gas gains enough heat before entering the process chamber, which in turn increases substrate throughput and deposition uniformity.

Advantages of the present disclosure include an improved pre-heat ring which has an outer peripheral edge circumscribing an opening. The outer peripheral edge has a radial width that allows for the flow of the precursor gas to be fully developed into a laminar-flow boundary layer over a top surface of the pre-heat ring before the precursor gas reaching the substrate. The boundary layer improves heat transfer from the pre-heat ring to the precursor gas. As a result, the precursor gas gains enough heat before entering the process chamber, which in turn increases substrate throughput and deposition uniformity. The opening of the pre-heat ring also allows an improved substrate support to be positioned therein. The substrate support has a recessed pocket surrounded by an angled support surface, which reduces a contacting surface area between the substrate and the substrate support. The recessed pocket has a surface that is slightly concave to prevent contact between the substrate and the recessed pocket, even when the substrate is bowed.

### Exemplary Dome Assembly

Described below is an exemplary implementation of a dome assembly. The dome assembly includes a curved upper dome for use in semiconductor process systems. The upper dome has a central window, and a peripheral flange engaging the central window and connecting with an outer circumference of the central window, wherein the central window is convex with respect to the substrate support, and the peripheral flange is at an angle of about 10° to about 30° with respect to a plane defined by a upper surface of the peripheral flange. The central window is curved toward the substrate which both acts to reduce the processing volume and allow for quick heating and cooling of the substrate during thermal processing. The peripheral flange has multiple curvatures which allow for thermal expansion of the central window without cracking or breaking.

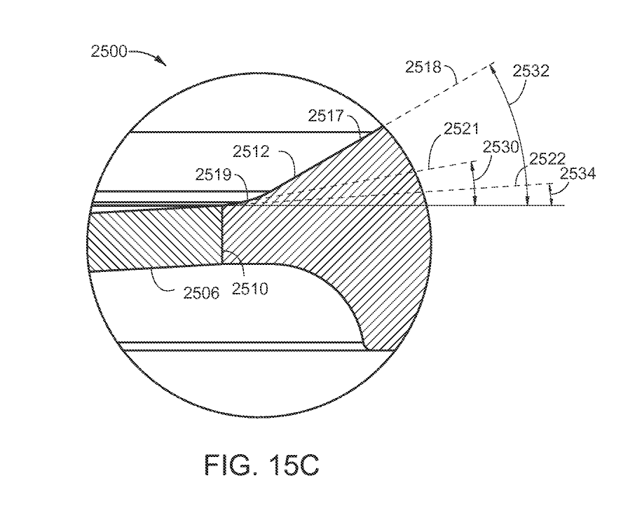

FIGS. 15A and 15B are schematic illustrations of an upper dome 2500 that may be used in a thermal process chamber according to implementations described herein. In one implementation, the thermal process chamber which may be adapted for use with implementations of the upper dome is the process chamber 100 of FIG. 2. FIG. 15A illustrates a top perspective view of the upper dome 2500. FIG. 15B illustrates a cross-section of the upper dome 2500. The upper dome 2500 has a substantially circular shape (FIG. 15A) and has a slightly concave outside surface 2502 and a slightly convex inside surface 2504 (FIG. 15B). As will be discussed in more detail below, the concave outside surface 2502 is sufficiently curved to oppose the compressive force of the exterior atmosphere pressure against the reduced internal pressure in the process chamber during substrate processing, while flat enough to promote the orderly flow of the process gas and the uniform deposition of the reactant material.

The upper dome 2500 generally includes a central window portion 2506 which is substantially transparent to infrared radiations, and a peripheral flange 2508 for supporting the central window portion 2506. The central window portion 2506 is shown as having a generally circular periphery. The peripheral flange 2508 engages the central window portion 2506 at and around a circumference of the central window portion 2506 along a support interface 2510. The central window portion 2506 may have a convex curvature with relation to a horizontal plane 2514 of the peripheral flange.

The central window portion 2506 of the upper dome 2500 may be formed from a material, such as clear quartz, that is generally optically transparent to the direct radiations from the lamps without significant absorption of desired wavelengths of radiation. Alternatively, the central window portion 2506 may be formed from a material having narrow band filtering capability. Some of the heat radiation re-radiated from the heated substrate and the substrate support may pass into the central window portion 2506 with significant absorption by the central window portion 2506. These re-radiations generate heat within the central window portion 2506, producing thermal expansion forces.

The central window portion 2506 is shown here as being circular in the length and width directions, with a circumference forming the boundary between the central window portion 2506 and the peripheral flange 2508. However, the central window portion 2506 may have other shapes as desired by the user.

The peripheral flange 2508 may be made from opaque quartz or other opaque material. The peripheral flange 2508, which may be made opaque, remains relatively cooler than the central window portion 2506, thereby causing the central window portion 2506 to bow outward beyond the initial room temperature bow. As a result, the thermal expansion within the central window portion 2506 is expressed as thermal compensation bowing. The thermal compensation bowing of the central window portion 2506 increases as the temperature of the process chamber increases. The central window portion 2506 is made thin and has sufficient flexibility to accommodate the bowing, while the peripheral flange 2508 is thick and has sufficient rigidness to confine the central window portion 2506.

In one implementation, the upper dome 2500 is constructed in a manner that the central window portion 2506 is an arc with a ratio of the radius of curvature to the width “W” of the central window portion 2506 which is at least 5:1. In one example, the radius of curvature to the width “W” is greater than 10:1, such as between about 10:1 and about 50:1. In another implementation, the radius of curvature to the width “W” is greater than 50:1, such as between about 50:1 and about 100:1. The width “W” is the width of the central window portion 2506 between the boundaries set by the peripheral flange 2508 as measured through the center of the central window portion 2506. Greater or less in the context of the above ratio refers to increasing or decreasing the value of the antecedent (i.e., the radius of curvature) proportionally to the consequent (i.e., the width “W”).

In another implementation shown in FIG. 15B, the upper dome 2500 is constructed in a manner that the central window portion 2506 is an arc with a ratio of the width “W” to the height “H” of the central window portion 2506 which is at least 5:1. In one example, the ratio of the width “W” to the height “H” is greater than 10:1, such as between about 10:1 and about 50:1. In another implementation, the ratio of the width “W” to the height “H” is greater than 50:1, such as between about 50:1 and about 100:1. The height “H” is the height of the central window portion 2506 between the boundaries set by a first boundary line 2540 and a second boundary line 2542. The first boundary line 2540 is tangent to the peak point of the portion of the curve in the central window portion 2506 facing the processing region 1220. The second boundary line 2542 intersects the points of the support interface 2510 furthest from the processing region 1220.

The upper dome 2500 may have a total outer diameter of about 200 mm to about 500 mm, such as about 240 mm to about 330 mm, for example about 295 mm. The central window portion 2506 may have a constant thickness of about 2 mm to about 10 mm, for example about 2 mm to about 4 mm, about 4 mm to about 6 mm, about 6 mm to about 8 mm, about 8 mm to about 10 mm. In some examples, the central window portion 2506 is about 3.5 mm to about 6.0 mm in thickness. In one example, the central window portion 2506 is about 4 mm in thickness.

The thickness of the central window portion 2506 provides a smaller thermal mass, enabling the upper dome 2500 to heat and cool rapidly. The central window portion 2506 may have an outer diameter of about 130 mm to about 250 mm, for example about 160 mm to about 210 mm. In one example, the central window portion 2506 is about 190 mm in diameter.

The peripheral flange 2508 may have a thickness of about 25 mm to about 125 mm, for example about 45 mm to about 90 mm. The thickness of the peripheral flange 2508 is generally defined as a thickness between the planar upper surface 2516 and the planar bottom surface 2520. In one example, the peripheral flange 2508 is about 70 mm in thickness. The peripheral flange 2508 may have a width of about 5 mm to about 90 mm, for example about 12 mm to about 60 mm, which may vary with radius. In one example, the peripheral flange 2508 is about 30 mm in width. If the liner assembly is not used in the process chamber, the width of the peripheral flange 2508 may be increased by about 50 mm to about 60 mm and the width of the central window portion 2506 is decreased by the same amount.

The central window portion 2506 has a thickness between 5 m and 8 mm, such as a 6 m thickness. The thickness of the central window portion 2506 of the upper dome 2500 is selected at a range as discussed above to ensure that shear stresses developed at the interface between the peripheral flange 2508 and the central window portion 2506 is addressed. In one implementation, the thinner quartz wall (i.e., the central window portion 2506) is a more efficient heat transfer medium so that less energy is absorbed by the quartz. The upper dome therefore remains relatively cooler. The thinner wall domes will also stabilize in temperature faster and respond to convective cooling quicker since less energy is being stored and the conductive path to the outside surface is shorter. Therefore, the temperature of the upper dome 2500 can be more closely held at a desired set point to provide better thermal uniformity across the central window portion 2506. In addition, while the central window portion 2506 conducts radially to the peripheral flange 2508, a thinner dome wall results in improved temperature uniformity over the substrate. It is also advantageous to not excessively cool the central window portion 2506 in the radial direction as this would result in unwanted temperature gradients which will reflect onto the surface of the substrate being processed and cause film uniformity to suffer.

FIG. 15C depicts a close up view of the connection between the peripheral flange 2508 and the central window portion 2506, according to one implementation. The peripheral flange 2508 has an angled flange surface 2512 which has at least a first surface 2517, indicated by a surface line 2518. The first surface 2517 forms a first angle 2532 with the planar upper surface 2516 of about 20° to about 30°. The angle of the first surface 2517 may be defined with the planar upper surface 2516 or the horizontal plane 2514. The planar upper surface 2516 is horizontal. The horizontal plane 2514 is parallel to the planar upper surface 2516 of the peripheral flange 2508.

The first angle 2532 can be more specifically defined as the angle between the planar upper surface 2516 of the peripheral flange 2508 (or the horizontal plane 2514) and a surface line 2518 on the convex inside surface 2504 of the central window portion 2506 that passes through an intersection of the central window portion 2506 and the peripheral flange 2508. In various implementations, the first angle 2532 between the horizontal plane 2514 and the surface line 2518 is generally less than 35°. Thus, the first surface 2517 forms an angle with the planar upper surface 2516 that is generally less than 35°. In one implementation, the first angle 2532 is about 6° to about 20°, such as between about 6° and about 8°, about 8° and about 10°, about 10° and about 12°, about 12° and about 14°, about 14° and about 16°, about 16° and about 18°, about 18° and about 20°. In one example, the first angle 2532 is about 10°. In another example, the first angle 2532 is about 30°. The angled flange surface 2512 with the first angle 2532 at about 20° provides structural support to the central window portion 2506 as supported by the peripheral flange 2508.

In another implementation, the angled flange surface 2512 can have one or more additional angles, depicted here as a second angle 2530 formed from a second surface 2519, as depicted by a surface line 2521. The second angle 2530 of the angled flange surface 2512 is an angle between a support angle 2534 of the peripheral flange 2508 and the first angle 2532. The support angle 2534 is the angle between the tangent surface 2522, which is formed from the convex inside surface 2504 at the support interface 2510, and the horizontal plane 2514. For example, if the support angle 2534 is 3° and the first angle 2532 is 30°, the second angle 2530 is between 3° and 30°. The second angle 2530 provides additional stress reduction by redirecting the forces with two sequential redirections, rather than a single redirection which further disperses the forces created by expansion and pressure.

The support angle 2534, the first angle 2532 and the second angle 2530 may have angles which create a fluid transition between end surfaces between the first surface 2517, the second surface 2519 and the tangent surface 2522. In one example, the tangent surface 2522 has an end surface which has a fluid transition with an end surface of the second surface 2519. In another example, the second surface 2519 has an end surface which has a fluid transition with an end surface of the first surface 2517. An end surface, as used herein, is formed at an imaginary separation between any of the first surface 2517, the second surface 2519 or the tangent surface 2522. A fluid transition between end surfaces is a transition between surfaces which connects without forming visible edges.

It is believed that the angle of the angled flange surface 2512 allows for thermal expansion of the upper dome 2500 while reducing the processing volume in the processing region 1220. Without intending to be bound by theory, scaling of existing upper domes for thermal processing will increase the processing volume, thus wasting reactant gases, decreasing throughput, decreasing deposition uniformity and increasing costs. The angled flange surface 2512 allows for expansion stresses to be absorbed without changing the ratio described above. By adding the angled flange surface 2512, the antecedent of the ratio of the radius of curvature to the width of the central window portion 2506 can be increased. By increasing the antecedent of the ratio, the curvature of the central window portion 2506 becomes more flat allowing for a smaller chamber volume.

Advantages of the upper dome provide many advantages in both stress compensation and minimizing intrusion into the processing region of the process chamber. The upper dome includes at least a curved central window and a peripheral flange having a plurality of angles. The curved central window reduces the space in the processing region and the substrate can be more efficiently heated and cooled during thermal processing. The peripheral flange has a plurality of angles formed in conjunction with the central window and away from the processing region. The plurality of angles provide stress relief to the central window during the heating and cooling steps. Further, the angles of the peripheral flange allow for a thinner flange and a thinner central window to further reduce process volume. By reducing process volume and component size, production and processing costs can be reduced without compromising quality in the end product or life cycle of the dome assembly.

Implementations described herein disclose an atmospheric epitaxial chamber. The atmospheric epitaxial chamber can incorporate one or more of the dome assembly, the liner assembly, the pre-heat ring, the substrate support, the inject inserts, the lamp assemblies including the reflectors or combinations thereof. Thus, through the benefits of the components described above and in combination, the epitaxial deposition chambers described herein allow for processing of larger substrates, while maintaining throughput, reducing costs and providing a reliably uniform deposition product.

While the foregoing is directed to implementations of the disclosed devices, methods and systems, other and further implementations of the disclosed devices, methods and systems may be devised without departing from the basic scope thereof, and the scope thereof is determined by the claims that follow.

1. A chamber, comprising:
a substrate support positioned in a processing region;
a radiant energy assembly comprising a plurality of radiant energy sources;
a liner assembly;
a dome assembly, at least a portion of which is positioned between the substrate support and the radiant energy assembly, the dome assembly comprising an upper dome and a lower dome, the upper dome comprising:
a curved central window portion having:
a width;
a height; and
a window curvature, the window curvature defined by a ratio of the width to the height being at least 10:1; and
a peripheral flange having:
a planar upper surface;
a planar lower surface; and
an angled flange surface, wherein the peripheral flange engages the central window portion at a circumference of the central window portion, and the angled flange surface has a first surface that forms a first angle with the planar upper surface that is less than 35 degrees; and
an inject insert coupled to the liner assembly.

2. The chamber of claim 1, wherein the angled flange surface further comprises a second surface between the circumference of the central window portion and the first surface.

3. The chamber of claim 2, wherein the second surface forms a second angle with the planar upper surface that is less than 15 degrees.

4. The chamber of claim 2, wherein the central window portion has a tangent surface with support angle, the support angle being less than 10 degrees.

5. The chamber of claim 4, wherein the tangent surface has an end surface that has a fluid transition with a first end surface of the second surface, and wherein the second surface has a second end surface which has a fluid transition with an end surface of the first surface.

6. The chamber of claim 1, wherein the peripheral flange has a thickness of less than 50 mm.

7. The chamber of claim 1, wherein the ratio of the height to the width is greater than 50:1

8. The chamber of claim 2, wherein the ratio of the size of the first angle to the size of the second angle is about 3:1.

9. A chamber, comprising:
a substrate support having:
an outer peripheral edge circumscribing a pocket, wherein the pocket has a concave surface that is recessed from the outer peripheral edge; and
an angled support surface disposed between the outer peripheral edge and the pocket, wherein the angled support surface is inclined with respect to a horizontal surface of the outer peripheral edge; and
a dome assembly positioned between the substrate support and the radiant energy assembly, the dome assembly comprising an upper dome and a lower dome, the upper dome comprising:
a convex central window portion having:
a width;
a height; and
a window curvature, the window curvature defined by the ratio of the width to the height being at least 10:1; and
a peripheral flange having:
a planar upper surface;
a planar lower surface; and
an angled flange surface, the peripheral flange engaging the central window portion at a circumference of the central window portion, the angled flange surface having a first surface that forms a first angle with the planar upper surface that is less than 35 degrees.

10. The chamber of claim 9, further comprising:
a ledge disposed between an outer diameter of the concave surface and an inner diameter of the outer peripheral edge.

11. The chamber of claim 10, wherein an inner diameter of the ledge is about 90% to about 97% of an inner diameter of the outer peripheral edge.

12. The chamber of claim 11, wherein the inner diameter of the outer peripheral edge is about 75% to about90% of an outer diameter of the outer peripheral edge.

13. The chamber of claim 9, further comprising a fillet radius formed at an interface between the outer peripheral edge and the angled support surface.

14. A chamber having an inner circumference, the chamber comprising:
a liner assembly, comprising:
a cylindrical body having an outer surface and an inner surface, the outer surface having an outer circumference less than the inner circumference, the inner surface forming walls of a process volume; and
a plurality of gas passages formed in connection with the cylindrical body;
an exhaust port positioned opposite to the plurality of gas passages;
a crossflow port positioned non parallel to the exhaust port; and
a thermal sensing port positioned separate from the crossflow port; and
an inject insert in fluid connection with the liner assembly, the inject insert comprising:
a monolithic body having:
an interior connecting surface for connecting with the liner assembly; and
an exterior surface to connect with a gas delivering device;
a plurality of inject ports formed through the monolithic body, each inject port forming an opening in the interior connecting surface and the exterior surface, the plurality of inject ports creating at least:
a first zone with a first number of inject ports of the plurality of inject ports;
a second zone with a second number of inject ports of the plurality of inject ports, the second number of inject ports being different from the first number of inject ports; and
a third zone with a third number of inject ports of the plurality of inject ports, the third number of inject ports being different from the first number of inject ports and the second number of inject ports; and
a plurality of inject inlets, each of the plurality of inject inlets being connected with at least one of the plurality of inject ports.

15. The chamber of claim 14, wherein the thermal sensing port, the crossflow port, the exhaust port and the plurality of gas passages are in a shared plane at the inner surface.

16. The chamber of claim 14, wherein the plurality of gas passages each have an entrance formed through the outer surface and an exit formed through the inner surface, wherein the entrances are not coplanar with the exits.

17. The chamber of claim 16, wherein at least one of the entrances is fluidly connected with more than one of the exits.

18. The chamber of claim 15, wherein the crossflow port is positioned at about a 0 degree position and a midpoint of the plurality of gas passages is positioned at a 90 degree position, the 0 degree position and the 90 degree position being measured from a bisecting line of the crossflow port.

19. The chamber of claim 18, wherein the thermal sensing port is positioned at about the 5 degree position, the position being measured from the bisecting line.

20. The chamber of claim 15, wherein the plurality of gas passages create a plurality of flow zones, the plurality of flow zones being parallel to one another and perpendicular to a bisecting line from the crossflow port.
